(19) United States
(12) Patent Application Publication
(10) Pub. No.: US 2026/0288005 A1
(43) Pub. Date: Sep. 24, 2026

(54) PHOTORESIST COMPOSITION AND METHOD FOR MANUFACTURING SEMICONDUCTOR DEVICE USING THE SAME

(71) Applicant: Samsung Electronics Co., Ltd., Suwon-si (KR)

(72) Inventors: Ji Yup KIM, Suwon-si (KR); Ju Hyeon PARK, Suwon-si (KR)

(21) Appl. No.: 19/555,198

(22) Filed: Mar. 3, 2026

(30) Foreign Application Priority Data
Mar. 19, 2025 (KR) 10-2025-0035293

(51) Int. Cl. G03F 7/039; G03F 7/004; H10P 14/68; H10P 50/00; H10P 76/20

(52) U.S. Cl. CPC G03F 7/0392; G03F 7/0045; H10P 14/683; H10P 50/692; H10P 50/71; H10P 50/73; H10P 76/2042

(57) ABSTRACT

An example chemically amplified photoresist composition and an example method for manufacturing a semiconductor device using the same are provided. The photosensitive polymer comprises a first repetition unit represented by any one of chemical formula 1a, chemical formula 1b, and chemical formula 1c, and each of the chemical formula 1a, the chemical formula 1b, and the chemical formula 1c includes an ester bond.

### CROSS-REFERENCE TO RELATED APPLICATION

This application claims priority from Korean Patent Application No. 10-2025-0035293, filed on Mar. 19, 2025 in the Korean Intellectual Property Office and all the benefits accruing therefrom under 35 U.S.C. 119, the contents of which in its entirety are herein incorporated by reference.

### BACKGROUND

A photolithography process using a photoresist composition is utilized to form various patterns included in the semiconductor device. For example, a photoresist film may be divided into an exposed portion and a non-exposed portion through an exposure process, and the exposed portion or the non-exposed portion may be removed through a developing process to form a photoresist pattern. Next, a desired pattern may be formed by patterning an etching target film using the photoresist pattern as an etching mask

Meanwhile, the chemically amplified photoresist may be used in the photolithography process. The chemically amplified photoresist is a highly sensitive photosensitive material that uses photoacid generated in the exposure process as catalysts, and may form fine and precise patterns by amplifying a chemical reaction activated by light.

### SUMMARY

The present disclosure relates to a photosensitive polymer that prevents a pattern shrinkage due to an exposure process, a photoresist composition including the photosensitive polymer that prevents the pattern shrinkage due to the exposure process, and a method for manufacturing a semiconductor device that uses the photosensitive polymer that prevents the pattern shrinkage due to the exposure process.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In general, according to some aspects, a photosensitive polymer comprises a first repetition unit represented by any one of following chemical formula 1a, chemical formula 1b and chemical formula 1c, and each of the chemical formula 1a, the chemical formula 1b and the chemical formula 1c includes an ester bond.

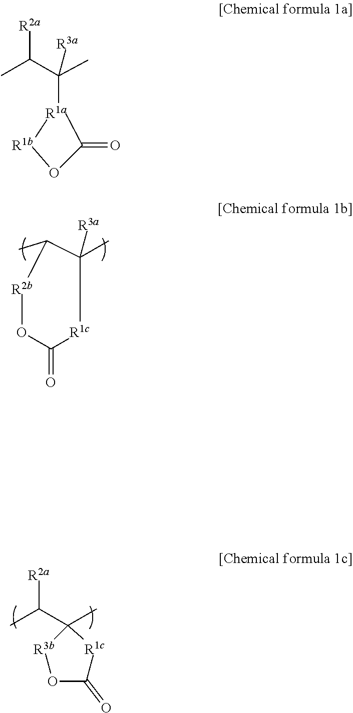

In the chemical formula 1a, the chemical formula 1b and the chemical formula 1c, R^{1a} is a trivalent linking group having 1 to 20 carbon atoms, each of R^{1b}, R^{2b} and R^{3b} is independently a divalent linking group having 3 to 20 carbon atoms including a tertiary carbon directly bonded to oxygen atom of the ester bond, R^{1c} is a single bond or a divalent linking group having 1 to 20 carbon atoms, each of R^{2a} and R^{3a} is independently a hydrogen atom, a hydroxyl group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 6 to 18 carbon atoms, a substituted or unsubstituted aryl alkyl group having 6 to 18 carbon atoms, or a halogen atom.

In general, according to some aspects, a photoresist composition comprises a photosensitive polymer which includes a first repetition unit represented by any one of following chemical formula 1a, following chemical formula 1b and following chemical formula 1c, each of the chemical formula 1a, the chemical formula 1b and the chemical formula 1c contains an ester bond, and a second repetition unit represented by following chemical formula 2, a photoacid generator, and a solvent.

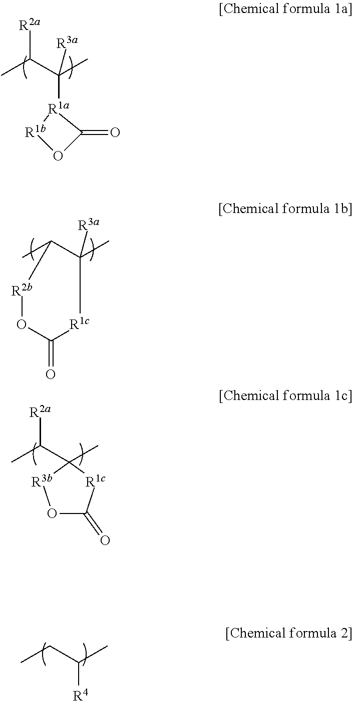

In the chemical formula 1a, the chemical formula 1b and the chemical formula 1c, R^{1a} is a trivalent linking group having 1 to 20 carbon atoms, each of R^{1b}, R^{2b} and R^{3b} is independently a divalent linking group having 3 to 20 carbon atoms including a tertiary carbon directly bonded to oxygen atom of the ester bond, R^{1c} is a single bond or a divalent linking group having 1 to 20 carbon atoms, each of R^{2a} and R^{3a} is independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 5 to 18 carbon atoms, a substituted or unsubstituted aryl alkyl group having 6 to 18 carbon atoms, or a halogen atom, and R⁴ is an aryl group having 6 to 30 carbon atoms including at least one selected from a hydroxyl group and an alkoxy group having 1 to 5 carbon atoms.

In general, according to some aspects, a method for manufacturing a semiconductor device comprises sequentially forming a target film and a photoresist film, on a substrate, performing an exposure process on the photoresist film, performing a development process on the photoresist film to form a photoresist pattern, and performing an etching process on the target film, using the photoresist pattern as an etching mask, wherein the photoresist film includes a photosensitive polymer including a first repetition unit represented by any one of following chemical formula 1a, following chemical formula 1b and following chemical formula 1c, each of the chemical formula 1a, the chemical formula 1b and the chemical formula 1c includes an ester bond.

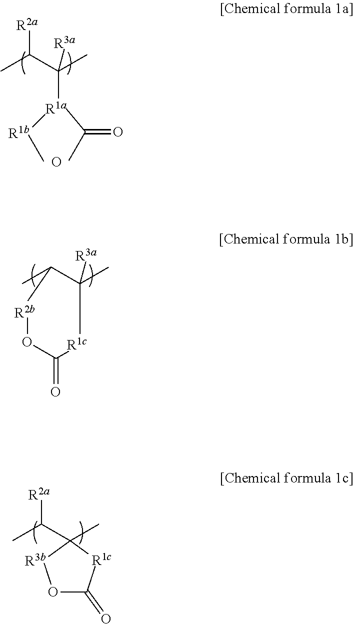

In the chemical formula 1a, the chemical formula 1b and the chemical formula 1c, R^{1a} is a trivalent linking group having 1 to 20 carbon atoms, each of R^{1b}, R^{2b}, and R^{3b} is independently a divalent linking group having 3 to 20 carbon atoms including a tertiary carbon directly bonded to oxygen atoms of the ester bond, R^{1c} is a single bond or a divalent linking group having 1 to 20 carbon atoms, each of R^{2a} and R^{3a} is independently a hydrogen atom, a hydroxyl group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 5 to 18 carbon atoms, a substituted or unsubstituted aryl alkyl group having 6 to 18 carbon atoms, or a halogen atom.

### BRIEF DESCRIPTION OF THE DRAWINGS

The above and other aspects and features of the present disclosure will become more apparent by describing in detail example implementations thereof with reference to the attached drawings.

FIGS. 1, 2, 3, 4, and 5 are intermediate stage diagrams for explaining an example of a method for manufacturing a semiconductor device.

### DETAILED DESCRIPTION

### Photosensitive Polymer

A photosensitive polymer according to example implementations will be described below. However, the following implementations are merely examples, and the present disclosure is not limited to these implementations.

As used herein, the term “substituted” means that hydrogen atom is substituted with deuterium, a halogen atom, a hydroxy group, a cyano group, a nitro group, an alkyl group, an amine group, an amino group, a silyl group, a thiol group, an aryl group, an alkoxy group, or a combination thereof. The term “unsubstituted” means that hydrogen atom is not substituted with another substituent and remains as a hydrogen atom.

The photosensitive polymer may be a polymer that induces a photochemical reaction by light. The light used for the photochemical reaction may include, but is not limited to, at least one of KrF excimer laser (248 nm), ArF excimer laser (193 nm), F2 excimer laser (157 nm) or extreme ultraviolet (EUV) (13.5 nm). In some implementations, in the photosensitive polymer, a solubility to a developer may increase by the photochemical reaction.

The photosensitive polymer may include a first repetition unit that is provided as an acid labile group by including an ester group in a side chain. For example, the photosensitive polymer may be manufactured through a polymerization reaction using a monomer corresponding to the first repetition unit. The acid labile group refers to a functional group that may be degraded by a photoacid. As an example, in a chemically amplified photoresist process, an ester bond of the first repetition unit may be degraded by a chain chemical reaction due to a photoacid during a post-exposure baking process. As a result, the exposed portion of the photoresist including the photosensitive polymer may change in polarity (e.g., from hydrophobic to hydrophilic) and change in solubility to a developer.

In the first repetition unit, both ends of the ester bond may be linked to the main chain to form a cyclic ester structure. In addition, in the first repetition unit, carbon directly bonded to the oxygen atom of the ester bond may be a tertiary carbon. Specifically, the first repetition unit may be represented by any one of following chemical formulas 1a, 1b, and 1c.

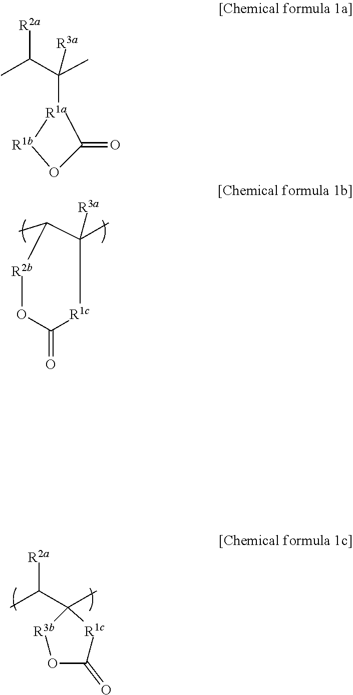

In the above chemical formula 1a, R^{1a} is a trivalent linking group having 1 to 20 carbon atoms. For example, R^{1a} may be a substituted or unsubstituted alkanetriyl group having 1 to 10 carbon atoms, a substituted or unsubstituted alkenetriyl group having 2 to 10 carbon atoms, a substituted or unsubstituted alkynetriyl group having 2 to 10 carbon atoms, a substituted or unsubstituted cycloalkanetriyl group having 3 to 20 carbon atoms, or a substituted or unsubstituted trivalent aryl group having 5 to 20 carbon atoms, a substituted or unsubstituted trivalent aryl alkyl group having 6 to 20 carbon atoms, or a substituted or unsubstituted trivalent alkyl aryl group having 6 to 20 carbon atoms.

In the above chemical formula 1a, R^{1b} is a divalent linking group having 3 to 20 carbon atoms that includes a tertiary carbon directly bonded to the oxygen atom of the ester bond. For example, R^{1b} may be a substituted or unsubstituted alkylene group having 3 to 10 carbon atoms, a substituted or unsubstituted alkenyl group having 5 to 10 carbon atoms, a substituted or unsubstituted alkynyl group having 5 to 10 carbon atoms, a substituted or unsubstituted cycloalkylene group having 4 to 20 carbon atoms, a substituted or unsubstituted arylene group having 5 to 20 carbon atoms, a substituted or unsubstituted aryl alkylene group having 6 to 20 carbon atoms, or a substituted or unsubstituted alkyl arylene group having 6 to 20 carbon atoms.

In the above chemical formulas 1a and 1c, R^{2a} is a hydrogen atom, a hydroxy group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 6 to 18 carbon atoms, a substituted or unsubstituted aryl alkyl group having 6 to 18 carbon atoms, or a halogen atoms. In some implementations, R^{2a} may be a hydrogen atom or a methyl group. When R^{2a} is a hydrogen atom or a methyl group, the polymerization rate of the photosensitive polymer may be improved.

In the above chemical formulas 1a and 1b, R^{3a} is a hydrogen atom, a hydroxy group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 6 to 18 carbon atoms, a substituted or unsubstituted aryl alkyl group having 6 to 18 carbon atoms, or a halogen atoms. In some implementations, R^{3a} may be a hydrogen atom, a methyl group, or an ethyl group. When R^{3a} is a hydrogen atom, a methyl group, or an ethyl group, the polymerization rate of the photosensitive polymer may be improved.

In the above chemical formulas 1b and 1c, R^{1c} is a single bond or a divalent linking group having 1 to 20 carbon atoms. For example, R^{1c} may be a single bond, a substituted or unsubstituted alkylene group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkylene group having 3 to 20 carbon atoms, a substituted or unsubstituted arylene group having 5 to 20 carbon atoms, a substituted or unsubstituted aryl alkylene group having 6 to 20 carbon atoms, or a substituted or unsubstituted alkyl arylene group having 6 to 20 carbon atoms. Here, “single bond” means that the carbon atom of the ester bond in chemical formula 1b or 1c is directly bonded to the main chain of the first repetition unit.

In the above chemical formula 1b, R^{2b} is a divalent linking group having 3 to 20 carbon atoms including a tertiary carbon directly bonded to the oxygen atom of the ester bond. For example, R^{1b} may be a substituted or unsubstituted alkylene group having 3 to 10 carbon atoms, a substituted or unsubstituted alkenyl group having 5 to 10 carbon atoms, a substituted or unsubstituted alkynyl group having 5 to 10 carbon atoms, a substituted or unsubstituted cycloalkylene group having 4 to 20 carbon atoms, a substituted or unsubstituted arylene group having 5 to 20 carbon atoms, a substituted or unsubstituted aryl alkylene group having 6 to 20 carbon atoms, or a substituted or unsubstituted alkyl arylene group having 6 to 20 carbon atoms.

In the above chemical formula 1c, R^{3b} is a divalent linking group having 3 to 20 carbon atoms that includes a tertiary carbon directly bonded to the oxygen atom of the ester bond. For example, R^{1b} may be a substituted or unsubstituted alkylene group having 3 to 10 carbon atoms, a substituted or unsubstituted alkenyl group having 5 to 10 carbon atoms, a substituted or unsubstituted alkynyl group having 5 to 10 carbon atoms, a substituted or unsubstituted cycloalkylene group having 4 to 20 carbon atoms, a substituted or unsubstituted arylene group having 5 to 20 carbon atoms, a substituted or unsubstituted aryl alkylene group having 6 to 20 carbon atoms, or a substituted or unsubstituted alkyl arylene group having 6 to 20 carbon atoms.

In some implementations, in the above chemical formula 1a, R^{1a} may be a trivalent phenyl group. For example, the chemical formula 1a may be represented by following chemical formula 1a′.

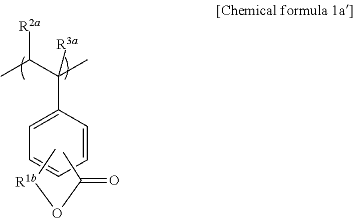

As an example, the first repetition unit may be represented by any one of the following structural formulas, but is not limited thereto.

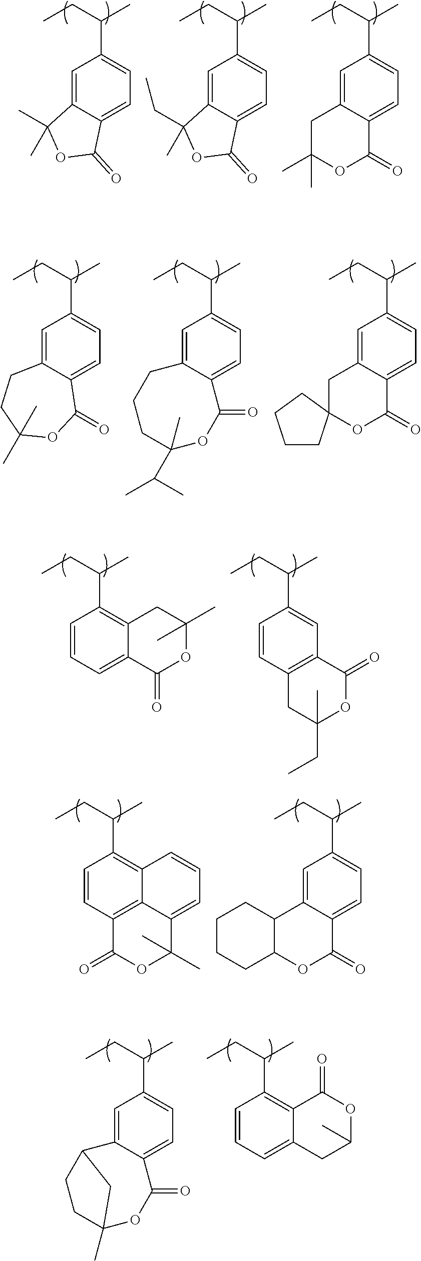

In some implementations, in the above chemical formula 1b, R^{1c} may be a single bond. For example, the above chemical formula 1b may be represented by following chemical formula 1b′.

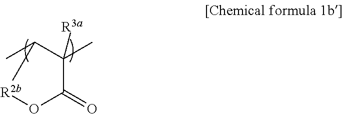

As an example, the first repetition unit may be represented by any one of the following structural formulas, but is not limited thereto.

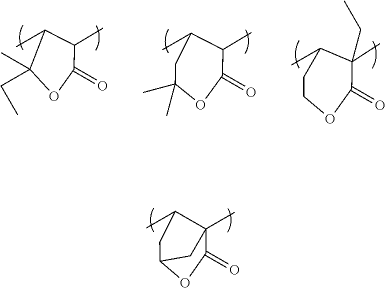

In some implementations, in the above chemical formula 1c, R^{1c} may be a single bond. For example, the above chemical formula 1c is represented by following chemical formula 1c′.

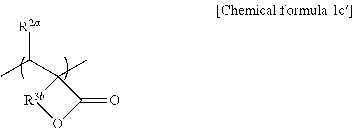

As an example, the first repetition unit may be represented by any one of the following structural formulas, but is not limited thereto.

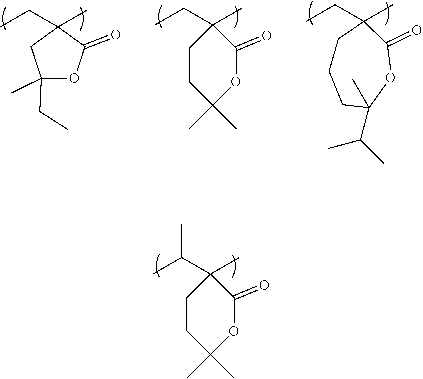

In some implementations, the photosensitive polymer may further include a second repetition unit provided as a sensitizing group. For example, the photosensitive polymer may be produced through a copolymerization reaction that uses a monomer corresponding to the first repetition unit and a monomer corresponding to the second repetition unit. The sensitizing group may induce the production of a photoacid (by a photoacid generator to be described below) by absorbing light and generating electrons. For example, the second repetition unit may be represented by following chemical formula 2.

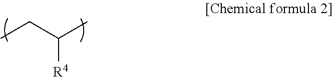

In the above chemical formula 2, R⁴ is an aryl group having 6 to 30 carbon atoms including at least one selected from a hydroxy group and an alkoxy group having 1 to 5 carbon atoms. As an example, R⁴ may be represented by any one of the following structural formulas, but is not limited thereto. In the following structural formulas, “*” represents a linking position.

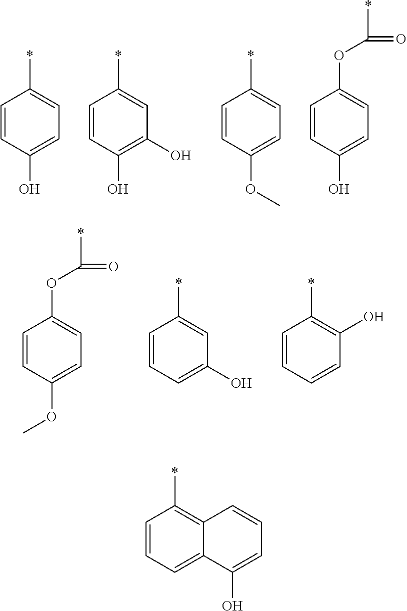

In some implementations, the photosensitive polymer may further include a third repetition unit for adjusting the polarity of the photosensitive polymer or improving the light absorbance of the photosensitive polymer. The third repetition unit may include, for example, but is not limited to, at least one of a lactone-based repetition unit, a halogenated (e.g., fluorinated or iodinated) hydrocarbon-based repetition unit, or a combination thereof.

In some implementations, the photosensitive polymer may have a weight average molecular weight (Mw) of about 2,000 to about 600,000. For example, the photosensitive polymer may have a weight average molecular weight of about 3,000 to about 200,000, or about 4,000 to about 100,000. The weight average molecular weight of the photosensitive polymer may be a value measured by gel permeation chromatography (GPC).

### Photoresist Composition

A photoresist composition according to the example implementations will be described below. However, the following implementations are merely examples, and the present disclosure is not limited to these implementations.

The photoresist composition may include the photosensitive composition, the photoacid generator (PAG), and a solvent.

The contents of the photosensitive composition may be appropriately adjusted in consideration of the viscosity of the photoresist composition, the film coating property, the quality of the pattern, and the like. For example, the contents of the photosensitive polymer relative to 100% by weight of the photoresist composition may be, but are not limited to, about 1% by weight to about 60% by weight, about 5% by weight to about 60% by weight, or about 5% by weight to about 40% by weight.

The photoacid generator may generate photoacid by light (e.g., KrF excimer laser, ArF excimer laser, F2 excimer laser, or extreme ultraviolet (EUV)). The photoacid generator may have a pKa (acid dissociation constant) of about-20 or more to less than about 1 by the light.

In some implementations, the photoacid generator may include at least one of a triarylsulfonium salts, diaryliodonium salts, sulfonates, or a combination thereof. For example, the photoacid generator may include, but is not limited to, at least one of triphenylsulfonium triflate, triphenylsulfonium antimonate, triphenylsulfonium difluoroalkyl sulfonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS or combinations thereof.

The contents of the photoacid generator may be appropriately adjusted in consideration the quality of the pattern, or the like. For example, the contents of the photoacid generator relative to 100% by weight of the photosensitive polymer may be, but are not limited to, about 1% by weight to about 80% by weight, about 5% by weight to about 70% by weight, about 10% by weight to about 70% by weight, or about 20% by weight to about 60% by weight.

The solvent may be included in the remaining portion of the photoresist composition. The solvent may be an organic solvent capable of dissolving the photosensitive polymer, or the like. For example, the solvent may include, for example, but is not limited to, at least one of ketones such as acetone, methyl ethyl ketone, cyclohexanone, methyl isoamyl ketone, and 2-heptanone; polyhydric alcohols such as ethylene glycol, ethylene glycol monoacetate, diethylene glycol, diethylene glycol monoacetate, propylene glycol, propylene glycol monoacetate, dipropylene glycol, monomethyl ether of dipropylene glycol monoacetate, monoethyl ether, monopropyl ether, monobutyl ether, and monophenyl ether, and their derivatives; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethyl ethoxyacetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanoate, 3-methoxybutyl acetate, and 3-methyl-3-methoxybutyl acetate; or aromatic hydrocarbons such as toluene and xylene.

In some implementations, the photoresist composition may further include a basic quencher. The basic quencher may trap the photoacid in the non-exposed portion when the photoacid generated from the photoacid generator diffuses to the non-exposed portion of the photoresist.

In some implementations, the basic quencher may include at least one of a primary aliphatic amine, a secondary aliphatic amine, a tertiary aliphatic amine, an aromatic amine, a heterocycle ring-including amine, a nitrogen-including compound having a carboxyl group, a nitrogen-including compound having a sulfonyl group, a nitrogen-including compound having a hydroxyl group, a nitrogen-containing compound having a hydroxyphenyl group, an alcoholic nitrogen-containing compound, an amide, an imide, a carbamate, an ammonium salt, or a combination thereof. For example, the basic quencher may include, but is not limited to, at least one of triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or combinations thereof.

In some implementations, the basic quencher may include a biodegradable base. The biodegradable base may trap photoacid before exposure, and may lose basicity when degraded by exposure. Accordingly, the biodegradable base may trap photoacid in the non-exposed portion and degraded in the exposed portion to improve the uniformity and planarity of the photoresist film.

In some implementations, the biodegradable base may include a carboxylate salt of a biodegradable cation or a sulfonate salt of a biodegradable cation. For example, the biodegradable cation may form a complex with a carboxylate having 1 to 20 carbon atoms. The carboxylic acid may be, for example, a formate, acetate, propionate, tartrate, succinate, cyclohexylcarboxylate, benzoate or salicylate.

The contents of the basic quencher may be appropriately adjusted in consideration of the quality of the pattern, or the like. For example, the contents of the basic quencher relative to 100% by weight of the photosensitive resin may be, but are not limited to, about 0.1% by weight to about 50% by weight, about 1% by weight to about 40% by weight, or about 10% by weight to about 30% by weight.

In some implementations, the photoresist composition may further include at least one of a surfactant, a dispersant, a moisture absorbing agent or a coupling agent.

The surfactant may improve the coating uniformity of the photoresist composition and improve wettability. In some implementations, the surfactant may include, but is not limited to, at least one of a sulfate ester salt, a sulfonate salt, a phosphate ester, a soap, an amine salt, a quaternary ammonium salt, a polyethylene glycol, an alkylphenol ethylene oxide adduct, a polyhydric alcohol, a nitrogen-containing vinyl polymer, or a combination thereof. For example, the surfactant may include at least one of an alkylbenzene sulfonate salt, an alkylpyridinium salt, a polyethylene glycol, or a quaternary ammonium salt. The contents of the surfactant relative to 100% by weight of the photoresist composition may be, for example, but are not limited to, about 0.001% by weight to about 3% by weight.

The dispersant may uniformly disperse each component constituting the photoresist composition in the photoresist composition. In some implementations, the dispersant may include, but is not limited to, at least one of epoxy resin, polyvinyl alcohol, polyvinyl butyral, polyvinyl pyrrolidone, glucose, sodium dodecyl sulfate, sodium citrate, oleic acid, linoleic acid, or a combination thereof. The content of the dispersant relative to 100% by weight of the photoresist composition may be, for example, but is not limited to, about 0.001% by weight to about 5% by weight.

The moisture absorbing agent may prevent deterioration due to moisture in the photoresist composition. For example, the moisture absorbing agent may prevent metals contained in the photoresist composition from being oxidized by moisture. In some implementations, the moisture absorbing agent may include, but is not limited to, at least one of polyoxyethylene nonylphenolether, polyethylene glycol, polypropylene glycol, polyacrylamide, or a combination thereof. The contents of the moisture absorbing agent relative to 100% by weight of the photoresist composition may be, for example, but are not limited to, about 0.001% by weight to about 10% by weight.

The coupling agent may improve an adhesion to an under film when the photoresist composition is coated on the under film. In some implementations, the coupling agent may include a silane coupling agent. The silane coupling agent may include, for example, but is not limited to, at least one of vinyltrimethoxysilane, vinyltriethoxysilane, vinyltrichlorosilane, vinyltris(β-methoxyethoxy) silane, 3-methacryloxypropyltrimethoxysilane, 3-acryloxypropyltrimethoxysilane, p-styryltrimethoxysilane, 3-methacryloxypropylmethyldimethoxysilane, 3-methacryloxypropylmethyldiethoxysilane, trimethoxy [3-(phenylamino) propyl]silane, or a combination thereof. The contents of the coupling agent relative to 100% by weight of the photoresist composition may be, for example, but are not limited to, about 0.001% by weight to about 5% by weight.

### Method for Manufacturing Semiconductor Device

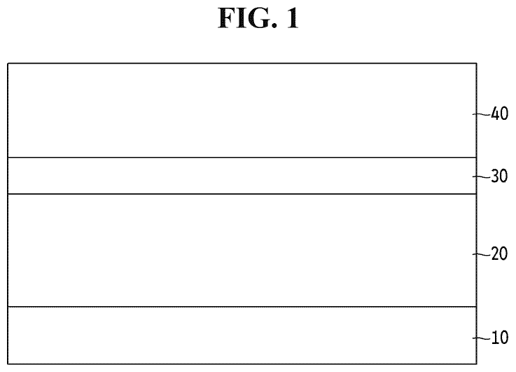

Hereinafter, a method for manufacturing a semiconductor device according to example implementations will be described with reference to FIGS. 1, 2, 3, 4, and 5. However, the following implementations are merely exemplary, and the present disclosure is not limited to these implementations.

FIGS. 1, 2, 3, 4, and 5 are intermediate stage diagrams for explaining an example of a method for manufacturing a semiconductor device.

Referring to FIG. 1, a target film 20, a mask film 30, and a photoresist film 40 are formed sequentially on a substrate 10.

The substrate 10 may be bulk silicon or silicon-on-insulator (SOI). The substrate 10 may be a silicon substrate or may include other materials, for example, silicon germanium, gallium arsenide, silicon germanium on insulator (SGOI), indium antimonide, lead telluride, indium arsenide, indium phosphide, gallium arsenide, or gallium antimonide. Alternatively, the substrate 10 may be one with an epitaxial layer formed on a base substrate, or may be a ceramic substrate, a quartz substrate, a display glass substrate, or the like.

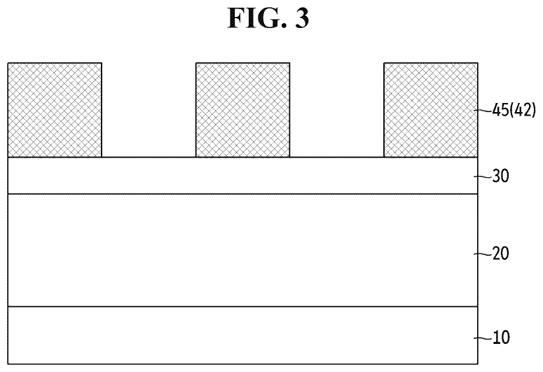

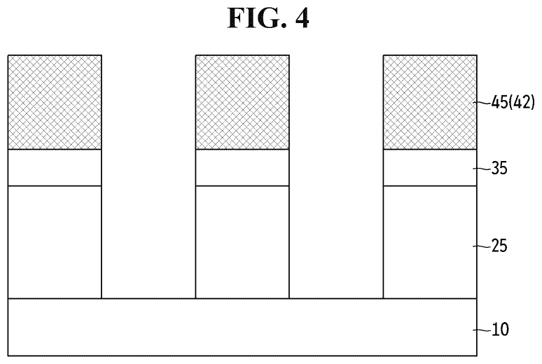

The target film 20 may be formed on the substrate 10. The target film 20 may be a layer on which an image is transferred from a photoresist pattern (45 of FIG. 3) to be described below and converted into a predetermined target pattern (25 of FIG. 4).

In some implementations, the target film 20 may include a conductive material such as a metal, a metal nitride, a metal silicide, or a metal silicide nitride film. In some implementations, the target film 20 may include an insulating material, such as silicon oxide, silicon nitride or silicon oxynitride. In some implementations, the target film 20 may include a semiconductor material, such as polysilicon.

The mask film 30 may be formed on the target film 20. The mask film 30 may be formed by, for example, being applied to the target film 20 by a spin-coating process and then performing a baking process. The mask film 30 may include, for example, but is not limited to, a spin-on hard mask (SOH).

The photoresist film 40 may be formed on the mask film 30. The photoresist film 40 may be formed on the mask film 30, for example, by a coating process such as a spin coating process, a dip coating process or a spray coating process.

The photoresist film 40 may include the above-mentioned photoresist composition. For example, the photoresist film 40 may include the photosensitive polymer, the photoacid generator, and the solvent.

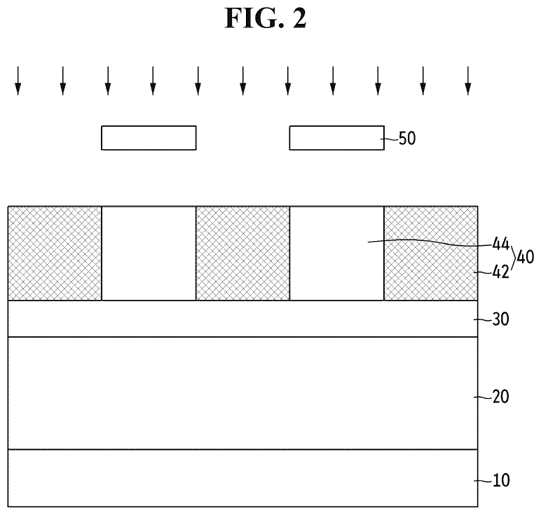

Referring to FIG. 2, an exposure process is performed on the photoresist film 40.

The photoresist film 40 may be divided into an exposed portion 42 and a non-exposed portion 44 by the exposure process. For example, an exposure mask 50 may be disposed on the photoresist film 40. When light is emitted from above the exposure mask 50 through a light source, the light that has passed through a transmission portion of the exposure mask 50 may be emitted to a part of the photoresist film 40 to form the exposed portion 42. The other part of the photoresist film 40 that is not irradiated with light due to the shielding portion of the exposure mask 50 may form the non-exposed portion 44. The light source may include at least one of a KrF excimer laser source, an ArF excimer laser source, an F2 excimer laser, extreme ultraviolet (EUV), or a combination thereof. In some implementations, the light source may be extreme ultraviolet (EUV). The photosensitive polymer of the exposed portion 42 may change polarity with light.

Referring to FIG. 3, a development process is performed to form a photoresist pattern 45.

In some implementations, the photoresist pattern 45 may be formed by a negative tone phenomenon (NTD) process. For example, the exposed portion 42 may remain in the development process to form the photoresist pattern 45, and the non-exposed portion 44 may be dissolved and removed by a developer used in the development process. The developer may include, for example, but is not limited to, ketones such as methyl ethyl ketone, acetone, 2-haptanone, and cyclohexanone; alcohols such as 4-methyl-2-propanol, 1-butanol, isopropanol, 1-propanol, and methanol; esters such as propylene glycol monomethyl ester acetate, ethyl acetate, ethyl lactate, n-butyl acetate, and butyrolactone; aromatic compounds such as benzene, xylene, and toluene; or combinations thereof.

In some implementations, the photoresist pattern 45 may be formed by a negative tone phenomenon (NTD) process. For example, a quaternary ammonium hydroxide compound such as tetraethylammonium hydroxide, tetrapropylammonium hydroxide, tetrabutylammonium hydroxide, or a combination thereof may be used as the developer.

Referring to FIG. 4, the target film 20 is patterned, using the photoresist pattern 45 as an etching mask.

For example, the mask pattern 35 and the target pattern 25 may be formed, by performing the etching process on the mask film 30 and the target film 20 using the photoresist pattern 45 as an etching mask. The etching process may include a dry etching process or a wet etching process, depending on the material constituting the target film 20, the etching selectivity between the photoresist pattern 45 and the target film 20, or the like.

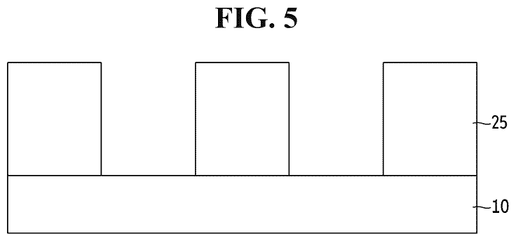

Referring to FIG. 5, the mask pattern 35 and the photoresist pattern 45 are removed.

The mask pattern 35 and the photoresist pattern 45 may be removed by, for example, an ashing process and/or a stripping process.

Accordingly, the target pattern 25 may be formed on the substrate 10. If the target film 20 includes a conductive material, the target pattern 25 may form a predetermined conductive pattern. If the target film 20 includes an insulating material, the target pattern 25 may form a predetermined insulating pattern. If the target film 20 includes a semiconductor material, the target pattern 25 may form a predetermined semiconductor pattern.

In the chemically amplified photoresist, a photosensitive polymer including an acid labile protective group may be used. The acid labile protective group may be separated by photoacid in the exposure process to change the polarity of the photosensitive polymer. For example, in a repetition unit including an ester group in a side chain, the acid labile protective group may be directly bonded to the oxygen atom of the ester bond. However, the acid labile protective group separated by photoacid in the exposure process may deteriorate the quality of the exposed portion as a by-product.

As an example, as in following reaction formula 1, a photosensitive polymer including a repetition unit represented by “m” and a repetition unit represented by “n” may be used as a photoresist composition. The repetition unit represented by “m” may be provided as an acid labile group, and the repetition unit represented by “n” may be provided as a sensitizing group. In addition, in the repetition unit represented by “m”, a tert-butyl group may be used as the acid labile protective group.

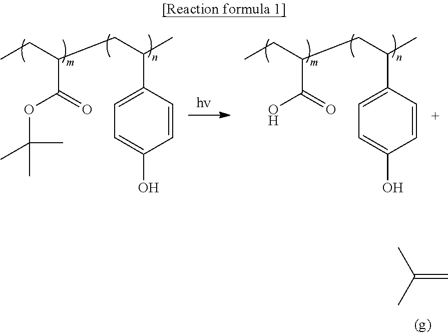

However, as shown in the above reaction formula 1, tert-butyl group may be released from the exposed portion of the photoresist as 2-methylpropene, which is a gaseous by-product in the exposure process. This may cause a pattern shrinkage in the exposed portion, and deteriorate the quality of the photoresist pattern.

In contrast, the photosensitive polymer may prevent the pattern shrinkage by not generating by-products in the exposure process. Specifically, as described above, in the first repetition unit provided by the acid labile group of the photosensitive polymer, both sides of the ester bond may be connected to the main chain to form a cyclic ester structure. In addition, in the first repetition unit, the carbon directly bonded to the oxygen atom of the ester bond may be a tertiary carbon. Therefore, the ester bond of the first repetition unit may not generate by-products even if it is degraded by the exposure process.

As an example, a photosensitive polymer including a repetition unit represented by “m” and a repetition unit represented by “n” may be used as a photoresist composition, as shown in following reaction formula 2. The repetition unit represented by “m” may be the first repetition unit provided by an acid labile group, and the repetition unit represented by “n” may be the second repetition unit provided by a sensitizing group.

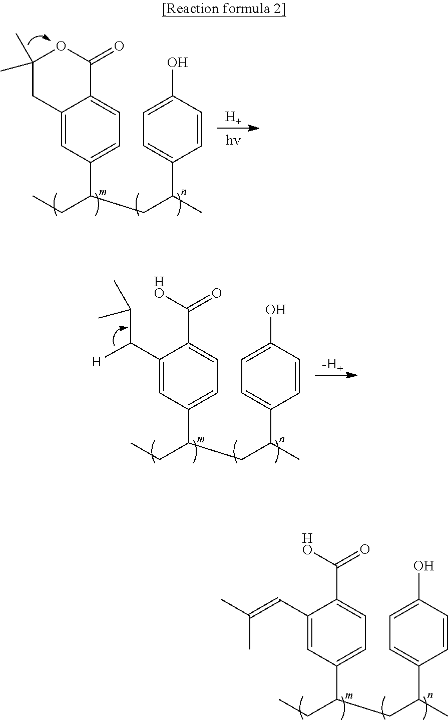

As shown in the above reaction formula 2, even if the third carbon directly bonded to the oxygen atom of the ester bond is separated from the oxygen atom by photoacid, it may still be bonded to the main chain (through a phenyl group). Accordingly, the photosensitive polymer may not generate gaseous by-products such as 2-methylpropene in the exposure process, and may provide a photoresist pattern with improved quality by preventing the pattern shrinkage.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described above with reference to the accompanying drawings, the present disclosure is not limited to the above implementations, and may be fabricated in various different forms. Those skilled in the art will appreciate that the present disclosure may be implemented in other specific forms without changing the technical spirit or essential features of the present disclosure. Accordingly, the above-described implementations should be understood in all respects as illustrative and not restrictive.

What is claimed is:

1. A photosensitive polymer comprising:
a first repetition unit represented by any one of chemical formula 1a, chemical formula 1b, and chemical formula 1c, wherein each chemical formula of the chemical formula 1a, the chemical formula 1b and the chemical formula 1c includes an ester bond,
wherein the chemical formula 1a is 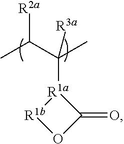
wherein the chemical formula 1b is 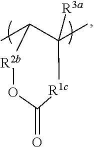
wherein the chemical formula 1c is 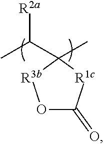
wherein R^{1a} is a trivalent linking group having 1 to 20 carbon atoms,
wherein each of R^{1b}, R^{2b}, and R^{3b} is an independent divalent linking group having 3 to 20 carbon atoms including a tertiary carbon directly bonded to an oxygen atom of the ester bond,
wherein R^{1c} is a single bond or a divalent linking group having 1 to 20 carbon atoms, and
wherein each of R^{2a} and R^{3a} is independently a hydrogen atom, a hydroxyl group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 6 to 18 carbon atoms, a substituted or unsubstituted aryl alkyl group having 6 to 18 carbon atoms, or a halogen atom.

2. The photosensitive polymer of claim 1,
wherein the chemical formula 1a is represented by chemical formula 1a′, and
wherein the chemical formula 1a′ is

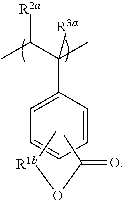

3. The photosensitive polymer of claim 2,
wherein the first repetition unit is represented by any one of the following structural formulas

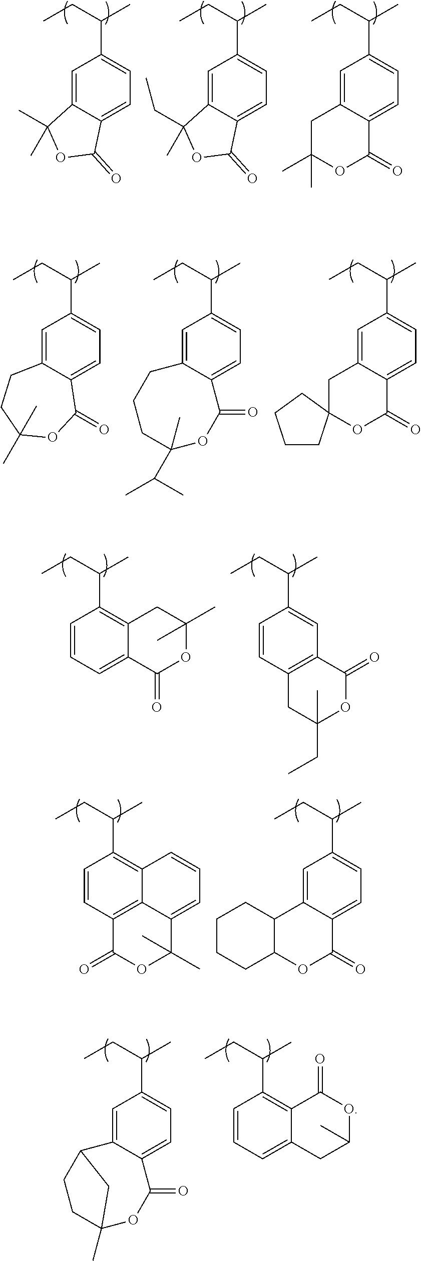

4. The photosensitive polymer of claim 1,
wherein the chemical formula 1b is represented by chemical formula 1b′, and
wherein the chemical formula 1b′ is

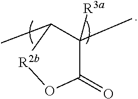

5. The photosensitive polymer of claim 4,
wherein the first repetition unit is represented by any one of following structural formulas

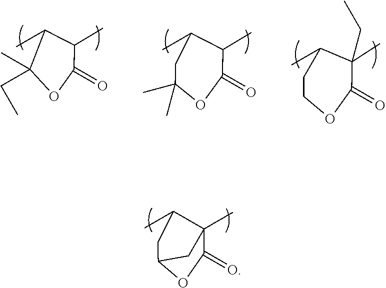

6. The photosensitive polymer of claim 1,
wherein the chemical formula 1c is represented by chemical formula 1c′, and
wherein the chemical formula 1c′ is

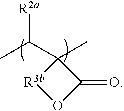

7. The photosensitive polymer of claim 6,
wherein the first repetition unit is represented by any one of the following structural formulas

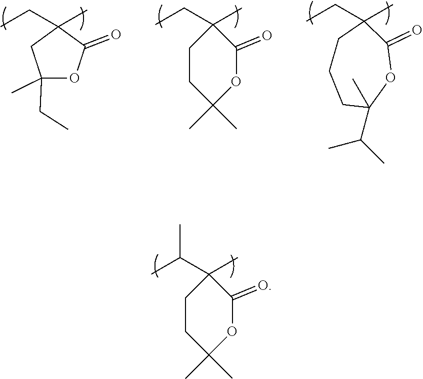

8. The photosensitive polymer of claim 1,
wherein the R^{2a} is a hydrogen atom or a methyl group.

9. The photosensitive polymer of claim 1,
wherein the R^{3a} is a hydrogen atom, a methyl group, or an ethyl group.

10. The photosensitive polymer of claim 1, comprising:
a second repetition unit represented by chemical formula 2,
wherein the chemical formula 2 is 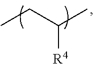
and
wherein R⁴ is an aryl group having 6 to 30 carbon atoms including at least one selected from a hydroxyl group and an alkoxy group having 1 to 5 carbon atoms.

11. A photoresist composition comprising:
a photosensitive polymer including:
a first repetition unit represented by any one of chemical formula 1a, chemical formula 1b, and chemical formula 1c, wherein each chemical formula of the chemical formula 1a, the chemical formula 1b, and the chemical formula 1c contains an ester bond; and
a second repetition unit represented by chemical formula 2;
a photoacid generator; and
a solvent,
wherein the chemical formula 1a is 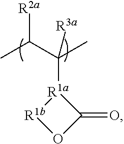
wherein the chemical formula 1b is 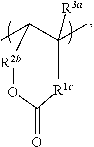
wherein the chemical formula 1c is 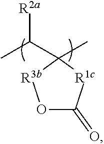
wherein the chemical formula 2 is 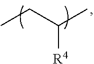
wherein R^{1a} is a trivalent linking group having 1 to 20 carbon atoms,
wherein each of R^{1b}, R^{2b}, and R^{3b} is an independent divalent linking group having 3 to 20 carbon atoms including a tertiary carbon directly bonded to an oxygen atom of the ester bond,
wherein R^{1c} is a single bond or a divalent linking group having 1 to 20 carbon atoms, wherein each of R^{2a} and R^{3a} is independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 5 to 18 carbon atoms, a substituted or unsubstituted aryl alkyl group having 6 to 18 carbon atoms, or a halogen atom, and
wherein R⁴ is an aryl group having 6 to 30 carbon atoms including at least one selected from a hydroxyl group and an alkoxy group having 1 to 5 carbon atoms.

12. The photoresist composition of claim 11,
wherein the first repetition unit is represented by chemical formula 1a′,
wherein the chemical formula 1a′ is 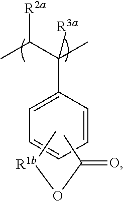
wherein R^{1b} is a divalent linking group having 3 to 20 carbon atoms including a tertiary carbon directly bonded to the oxygen atom of the ester bond,
wherein R^{2a} is a hydrogen atom or a methyl group, and
wherein R^{3a} is a hydrogen atom, a methyl group, or an ethyl group.

13. The photoresist composition of claim 11,
wherein the first repetition unit is represented by chemical formula 1b′,
wherein the chemical formula 1b′ is 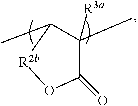
wherein R^{2b} is a divalent linking group having 3 to 20 carbon atoms including a tertiary carbon directly bonded to the oxygen atom of the ester bond, and
wherein R^{3a} is a hydrogen atom, a methyl group, or an ethyl group.

14. The photoresist composition of claim 11,
wherein the first repetition unit is represented by chemical formula 1c′,
wherein the chemical formula 1c′ is 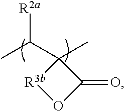
wherein R^{3b} is a divalent linking group having 3 to 20 carbon atoms including a tertiary carbon directly bonded to the oxygen atom of the ester bond, and
wherein R^{2a} is a hydrogen atom or a methyl group.

15. The photoresist composition of claim 11,
wherein the photoacid generator is configured to generate a photoacid by extreme ultraviolet (EUV).

16. The photoresist composition of claim 11, comprising:
a basic quencher.

17. A method for manufacturing a semiconductor device, the method comprising:
sequentially forming a target film and a photoresist film on a substrate;
performing an exposure process on the photoresist film;
performing a development process on the photoresist film to form a photoresist pattern; and
performing an etching process on the target film by using the photoresist pattern as an etching mask,
wherein the photoresist film includes a photosensitive polymer including a first repetition unit represented by any one of chemical formula 1a, chemical formula 1b, and chemical formula 1c, and each chemical formula of the chemical formula 1a, the chemical formula 1b, and the chemical formula 1c includes an ester bond,
wherein the chemical formula 1a is 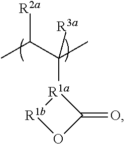
wherein the chemical formula 1b is 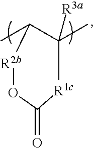
wherein the chemical formula 1c is 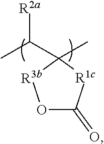
wherein R^{1a} is a trivalent linking group having 1 to 20 carbon atoms,
wherein each of R^{1b}, R^{2b}, and R^{3b} is an independent divalent linking group having 3 to 20 carbon atoms including a tertiary carbon directly bonded to an oxygen atoms of the ester bond,
wherein R^{1c} is a single bond or a divalent linking group having 1 to 20 carbon atoms, and
wherein each of R^{2a} and R^{3a} is independently a hydrogen atom, a hydroxyl group, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted alkoxy group having 1 to 3 carbon atoms, a substituted or unsubstituted cycloalkyl group having 3 to 20 carbon atoms, a substituted or unsubstituted aryl group having 5 to 18 carbon atoms, a substituted or unsubstituted aryl alkyl group having 6 to 18 carbon atoms, or a halogen atom.

18. The method for manufacturing the semiconductor device of claim 17,
wherein the photosensitive polymer comprises a second repetition unit represented by chemical formula 2,
wherein the chemical formula 2 is 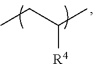
and
wherein R⁴ is an aryl group having 6 to 30 carbon atoms including at least one selected from a hydroxyl group and an alkoxy group having 1 to 5 carbon atoms.

19. The method for manufacturing the semiconductor device of claim 17,
wherein the first repetition unit is configured to not generate a gaseous by-product in the exposure process.

20. The method for manufacturing the semiconductor device of claim 17,
wherein the development process includes a negative tone development (NTD) process.
